(19) United States
(12) Patent Application Publication
(10) Pub. No.: US 2015/0021622 A1
(43) Pub. Date: Jan. 22, 2015

(54) LIGHT-EMITTING ELEMENT AND METHOD FOR MANUFACTURING SAME

(71) Applicant: PANASONIC CORPORATION, Osaka (JP)

(72) Inventors: Katsumi Sugiura, Toyama (JP); Hidemi Takeishi, Kagoshima (JP); Kazuyuki Yamae, Nara (JP); Kengo Tokuoka, Kagoshima (JP); Masahiro Kume, Kagoshima (JP); Masanori Hiroki, Kagoshima (JP); Yoshiaki Hasegawa, Toyama (JP)

(21) Appl. No.: 14/378,603

(22) PCT Filed: Feb. 20, 2013
(86) PCT No.: PCT/JP2013/000935

§ 371 Date: Aug. 13, 2014

(30) Foreign Application Priority Data
Mar. 9, 2012 (JP) 2012-052675

(51) Int. Cl. H01L 33/22; H01L 33/32; H01L 33/00

(52) U.S. Cl. CPC H01L 33/22; H01L 33/0075; H01L 33/32; H01L 2933/0058
USPC 257/76; 257/98; 438/29

(57) ABSTRACT

In a light emitting element, a semiconductor layer including a light emitting layer is stacked on a GaN substrate 11, and a surface of the GaN substrate 11 opposite to the stacked semiconductor layer serves as a main light emission surface S. At the main light emission surface S, quadrangular pyramid shaped protrusions 11a which are continuously arranged and whose standing direction F2 is displaced from a stacking direction of the semiconductor layer are formed. In each protrusion 11a, fine asperities are, by etching, preferably formed at least at an inclined surface having a small inclination angle. Moreover, each protrusion 11a may be in a truncated shape, but is preferably formed in a pointed shape.

### TECHNICAL FIELD

The present disclosure relates to a light emitting element in which a semiconductor layer including a light emitting layer is stacked on a substrate and to the method for manufacturing the light emitting element.

### BACKGROUND ART

In order to realize higher luminance, it is important for a light emitting element in which a semiconductor layer including a light emitting layer is stacked on a substrate to improve light extraction efficiency. In order to reduce light emitted from the light emitting layer and totally reflected, as return light, off a main light emission surface, i.e., a surface of the substrate opposite to the stacked semiconductor layer, it has been known that fine asperities are, by wet etching, formed at the substrate in the flip-chip mounted light emitting element. Besides forming the fine asperities at the substrate, a conventional light emitting element described in, e.g., Patent Document 1 has been known.

In the GaN-based thin-film semiconductor light emitting element described in Patent Document 1, raised protrusions are one-dimensionally or two-dimensionally patterned at a second principal surface of a multilayer structure. Patent Document 1 describes, as examples, protrusions formed in a truncated pyramid shape or a truncated cone shape.

### CITATION LIST

### Patent Document

PATENT DOCUMENT 1: Japanese Translation of PCT Application No. 2005-535143

### SUMMARY OF THE INVENTION

### Technical Problem

However, the light extraction efficiency is not enough in the light emitting element described in Patent Document 1, and further improvement of the light extraction efficiency has been demanded.

The present disclosure aims to provide a light emitting element capable of further improving light extraction efficiency and the method for manufacturing the light emitting element.

### Solution to the Problem

In a light emitting element of the present disclosure, a semiconductor layer including a light emitting layer is stacked on a substrate, and a surface of the substrate opposite to the stacked semiconductor layer serves as a main light emission surface. The light emitting element includes protrusions continuously arranged on the main light emission surface. A standing direction of each protrusion is displaced from a stacking direction of the semiconductor layer. Displacement of the standing direction of the protrusion from the stacking direction of the semiconductor layer means that the direction extending between a center-of-gravity line passing through the centers of gravity of the bases of the protrusions and an apex line passing through the apexes of the protrusions is not parallel to the stacking direction (direction perpendicular to the substrate surface) of the semiconductor layer, and forms a predetermined angle with respect to the stacking direction of the semiconductor layer. For example, in the case where the protrusion is in a quadrangular pyramid shape, the line (extending in the standing direction) connecting between the center of gravity of the base, which is parallel to the substrate surface, of the protrusion and the apex of the protrusion is not parallel to the stacking direction of the semiconductor layer.

A method for manufacturing a light emitting element according to the present disclosure includes a stacking step of stacking a semiconductor layer including a light emitting layer on a substrate; and a processing step of continuously forming protrusions each standing in a direction displaced from a stacking direction of the semiconductor layer by forming grooves at a main light emission surface of the substrate opposite to the stacked semiconductor layer while a cutter is being moved in a grid pattern, each groove being formed of a wall having a small inclination angle and a wall having a large inclination angle.

### Advantages of the Invention

According to the present disclosure, since the protrusion is in a three-dimensional shape formed of an inclined surface having a small inclination angle and an inclined surface having a large inclination angle, the probability that light emitted from the light emitting layer reaches the main light emission surface of the substrate at an angle below a critical angle can be increased. Thus, light extraction efficiency can be further improved.

### BRIEF DESCRIPTION OF THE DRAWINGS

FIG. 1 is a cross-sectional view of a light emitting element of an embodiment of the present disclosure.

FIG. 2(a) is a view which illustrates protrusions illustrated in FIG. 1 and formed at a main light emission surface. FIG. 2(b) is a cross-sectional view along an A-A line. FIG. 2(c) is a view illustrating a standing direction of the protrusion.

FIG. 3(a) is a view illustrating the state in which a defocus amount is small in the case where the protrusions of the light emitting element illustrated in FIG. 1 are formed by a laser scriber. FIG. 3(b) is a view illustrating the state in which the defocus amount is increased.

FIG. 4 is a view illustrating the case where the protrusions of the light emitting element illustrated in FIG. 1 are formed by a dicer.

FIG. 5(a) is a cross-sectional view illustrating the state before surface roughening in the case where surfaces of the protrusions are roughened. FIG. 5(b) is a cross-sectional view illustrating the state in which inclined surfaces of the protrusions having a small inclination angle are roughened.

FIG. 6(a) is a table of comparison between the luminance (relative value) of the light emitting element (invented device) of the embodiment of the present disclosure and the luminance (relative value) of a conventional light emitting element (comparative device), which is provided to describe advantages of the invented device. FIG. 6(b) is a graph showing the relationship between an inclination angle and luminance (relative value).

FIG. 7(a) is a view illustrating a main light emission surface of a first variation of the light emitting element of the embodiment. FIG. 7(b) is a cross-sectional view along a B-B line.

FIG. 8(a) is a view illustrating a main light emission surface of a second variation of the light emitting element of the embodiment. FIG. 8(b) is a cross-sectional view along a C-C line.

FIG. 9 is a view illustrating a main light emission surface of a third variation of the light emitting element of the embodiment.

FIG. 10(a) is a plan view illustrating a light emitting element of a fourth variation. FIG. 10(b) is a cross-sectional view along a D-D line.

FIG. 11(a) is a plan view illustrating a light emitting element of a fifth variation. FIG. 11(b) is a cross-sectional view along an E-E line. FIG. 11(c) is a cross-sectional view of a light emitting device.

FIG. 12(a) is a plan view illustrating a light emitting element of a sixth variation. FIG. 12(b) is a cross-sectional view along an F-F line.

FIG. 13(a) is a graph showing the relationship between a chip shape and light extraction efficiency. FIG. 13(b) is a plan view of a triangular light emitting element. FIG. 13(c) is a cross-sectional view along a G-G line. FIG. 13(d) is a plan view of a hexagonal light emitting element. FIG. 13(e) is a cross-sectional view along an H-H line.

FIG. 14(a) is an enlarged cross-sectional view (photo image) of fine asperities. FIG. 14(b) is a diagram illustrating a crystal structure of a GaN substrate. FIG. 14(c) is a view (photo image) showing an N-face of the GaN substrate. FIG. 14(d) is an enlarged partial view (photo image) of FIG. 14(c). FIG. 14(f) is a view (photo image) showing a surface of the GaN substrate at which protrusions are formed. FIG. 14(g) is an enlarged partial view (photo image) of FIG. 14(g).

FIG. 15 is a cross-sectional view illustrating a light emitting element of a preferable embodiment.

FIGS. 16(a)-16(h) are views illustrating variations in which the region where no protrusions are formed is formed.

### DESCRIPTION OF EMBODIMENTS

In a light emitting element of a preferable aspect of the present disclosure, a semiconductor layer including a light emitting layer is stacked on a substrate, and a surface of the substrate opposite to the stacked semiconductor layer serves as a main light emission surface. The light emitting element includes protrusions continuously arranged on the main light emission surface. A standing direction of each protrusion is displaced from a stacking direction of the semiconductor layer.

According to the foregoing configuration, since the standing direction of the protrusion is displaced from the stacking direction of the semiconductor layer, the protrusion is in a three-dimensional shape formed of a gentle inclined surface (i.e., an inclined surface having a small inclination angle) and a steep inclined surface (i.e., an inclined surface having a large inclination angle). Thus, the probability that light emitted from the light emitting layer reaches the main light emission surface of the substrate at an angle below a critical angle can be increased.

In the preferable aspect, fine asperities are formed at least at the inclined surface of each protrusion having the small inclination angle.

According to the foregoing configuration, when the standing direction of the protrusion is displaced from the stacking direction of the semiconductor layer, the protrusion is in a three-dimensional shape formed of a broad inclined surface having a small inclination angle and a narrow inclined surface having a large inclination angle. Thus, since the fine asperities are formed at least at the inclined surface having the small inclination angle, light extraction efficiency can be further improved.

In the preferable aspect, the protrusions are arranged in a matrix of lines and columns, and a line direction and/or a column direction of the protrusions are non-parallel to an end surface of the substrate.

According to the foregoing configuration, the line direction and/or the column direction of the protrusions are non-parallel to the end surface of the substrate. Thus, when a wafer to be the substrates is divided into pieces by breaking after the semiconductor layer is stacked on the wafer and scribe grooves for diving the light emitting elements from each other are formed at the wafer, the wafer can be prevented from being mistakenly divided at the groove between adjacent ones of the protrusions by breaking.

In the preferable aspect, each protrusion is formed in a pointed shape or a truncated shape.

According to the foregoing configuration, when the protrusions are formed in the pointed shape, no surfaces parallel to the light emitting layer (i.e., a surface of the stacked semiconductor layer) are formed, and therefore broader inclined surfaces can be ensured due to the pointed shape of the protrusions. Thus, the probability that light reaches the main light emission surface at the angle below the critical angle can be further increased. Moreover, when the protrusions are formed in the truncated shape, a horizontal surface is formed at the apex of each protrusion. Since the horizontal surfaces closely contact a suction surface of a collet, the light emitting element can be stably delivered when the collect is used to suck and deliver the light emitting element.

In the preferable aspect, each protrusion is formed in a pyramid shape.

According to the foregoing configuration, since the protrusion is formed in such a pyramid shape that the center axis thereof is eccentric with respect to the stacking direction of the semiconductor layer, the protrusion is in a three-dimensional shape formed of an inclined surface having a small inclination angle and an inclined surface having a large inclination angle. Thus, the probability that light emitted from the light emitting layer reaches the main light emission surface of the substrate at the angle below the critical angle can be increased.

The inclined surfaces can be easily formed in such a manner that cutting is performed using, e.g., laser or a dicer.

A method for manufacturing a light emitting element according to a preferable aspect of the present disclosure includes a stacking step of stacking a semiconductor layer including a light emitting layer on a substrate; and a processing step of continuously forming protrusions each standing in a direction displaced from a stacking direction of the semiconductor layer by forming grooves at a main light emission surface of the substrate opposite to the stacked semiconductor layer while a cutter is being moved in a grid pattern, each groove being formed of a wall having a small inclination angle and a wall having a large inclination angle.

According to the foregoing configuration, while the cutter is being moved in the grid pattern, the grooves each formed of the wall having the small inclination angle and the wall having the large inclination angle are formed. Thus, the protrusions whose standing direction is displaced from the stacking direction of the semiconductor layer can be formed.

In the preferable aspect, at the processing step, the main light emission surface is irradiated with laser light by a laser device serving as the cutter to form V-shaped grooves, and then, while the defocus amount of a collecting lens is being increased, each V-shaped groove is, in order to form the grooves having an increased width, expanded along one of walls of the each V-shaped groove such that a depth of the one of walls of the each V-shaped groove gradually decreases in a direction perpendicular to a groove direction.

According to the foregoing configuration, while the defocus amount of the collecting lens is being adjusted, the main light emission surface is irradiated with the laser light. Thus, the protrusions are formed.

In the preferable aspect, at the processing step, a rotary cutting blade serving as the cutter is moved in a state in which the rotary cutting blade is inclined such that an inclination angle of a blade edge surface of the rotary cutting blade with respect to the main light emission surface and an inclination angle of a blade side surface of the rotary cutting blade with respect to the main light emission surface are different from each other, thereby forming the grooves.

According to the foregoing configuration, the protrusions can be formed in such a manner the rotary cutting blade is moved with the inclination angle of the rotary cutting blade being adjusted.

In the preferable aspect, at the processing step, when the cutter is moved in the grid pattern to form the grooves, the cutter is moved in a direction non-parallel to a scribe groove to be an end surface of the substrate.

According to the foregoing configuration, a line direction and/or a column direction of the protrusions are non-parallel to the end surface of the substrate. Thus, when a wafer to be the substrates is divided into pieces by breaking after the semiconductor layer is stacked on the wafer and scribe grooves for diving the light emitting elements from each other are formed at the wafer, the wafer can be prevented from being mistakenly divided at the groove between adjacent ones of the protrusions by breaking.

### Embodiment

A light emitting element of an embodiment of the present disclosure will be described with reference to drawings.

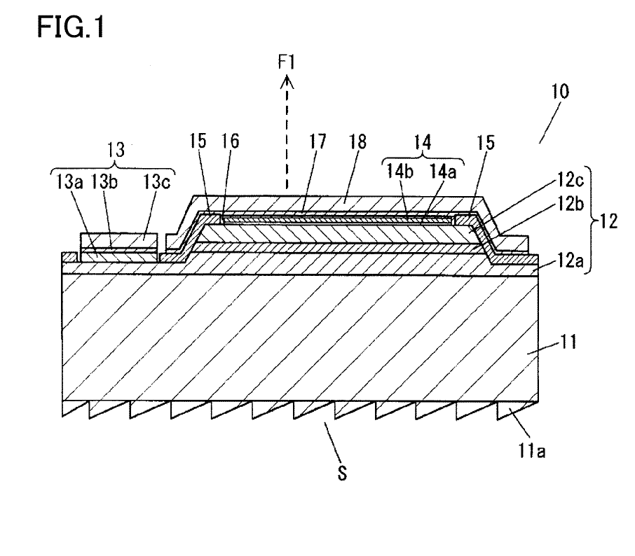

Referring to FIG. 1, a light emitting element 10 is a flip-chip LED in which a semiconductor layer is stacked on a substrate having light transmitting properties and in which electrodes configured to supply power are provided. In the present embodiment, a c-plane GaN substrate 11 having a thickness of about 100 μm is provided as the substrate. Since a too thin substrate is likely to cause chip cracking at a processing step and a mounting step, the thickness of the GaN substrate 11 is preferably equal to or greater than 70 μm.

At a stacking step, an N-GaN layer 12a which is an n-type layer, a light emitting layer 12b, and a P-GaN layer 12c which is a p-type layer are, as a semiconductor layer 12, stacked on a +c-plane (Ga-face) of the GaN substrate 11. A buffer layer may be formed between the GaN substrate 11 and the N-GaN layer 12a. For example, Si or Ge may be preferably used as an n-type dopant with which the N-GaN layer 12a is doped. The N-GaN layer 12a is formed so as to have a thickness of about 2 μm.

The light emitting layer 12b contains at least Ga and N, and contains an appropriate amount of In if necessary. Thus, a desired emission wavelength can be obtained. The light emitting layer 12b may have a single-layer structure, but may alternatively have, e.g., a multiple quantum well structure in which at least an InGaN layer and a GaN layer are alternately stacked on each other. The light emitting layer 12b having the multiple quantum well structure can further improve luminance.

The P-GaN layer 12c may be an AlGaN layer having a thickness of about 120 nm.

The semiconductor layer 12 can be formed on the GaN substrate 11 by an epitaxial growth technique such as MOVPE, but may be stacked on the GaN substrate 11 by, e.g., hydride vapor phase epitaxy (HYPE) or molecular beam epitaxy (MBE).

An n-electrode 13 and a p-electrode 14 are provided in the semiconductor layer 12.

The n-electrode 13 is provided on a region of the N-GaN layer 12a formed in such a manner that the P-GaN layer 12c, the light emitting layer 12b, and the N-GaN layer 12a are partially etched. The n-electrode 13 is formed such that an Al layer 13a, a Ti layer 13b, and an Au layer 13c are stacked on each other.

The p-electrode 14 is stacked on part of the P-GaN layer 12c remaining after etching. The p-electrode 14 is formed such that a Ni layer 14a and an Ag layer 14b are stacked on each other. Since the p-electrode 14 includes the Ag layer 14b having high reflectivity, the p-electrode 14 functions as a reflector electrode.

The Ni layer 14a functions as an adhesive layer configured to improve adhesion between the P-GaN layer 12c and the Ag layer 14b. The thickness of the Ni layer 14a may fall within a range of 0.1 to 5 nm.

A SiO₂ layer 15 is, at the periphery of the p-electrode 14, stacked on a side surface of the P-GaN layer 12c exposed by etching, a side surface of the light emitting layer 12b exposed by etching, and a surface of the N-GaN layer 12a exposed by etching, thereby forming a protective layer.

A first Ti layer 16 functioning as a barrier electrode and made of Ti is stacked on the p-electrode 14 so as to have a thickness of about 400 nm. The first Ti layer 16 is formed across an area broader than the p-electrode 14. The first Ti layer 16 can be formed as follows. The SiO₂ layer 15 is stacked, and the p-electrode 14 is stacked. Then, a mask pattern for forming the p-electrode 14 is removed, and Ti is stacked. Subsequently, the first Ti layer 16 formed across an area broader than the Ag layer 14b is formed by wet etching. In this manner, the first Ti layer 16 having a contour shape larger than that of the p-electrode 14 is formed.

A second Ti layer 17 is further formed on the SiO₂ layer 15 functioning as the protective layer and the first Ti layer 16 functioning as the barrier electrode. The second Ti layer 17 is formed so as to have a thickness of about 150 nm.

An Al layer may be formed between the first Ti layer 16 and the second Ti layer 17.

An Au layer 18 is stacked on the second Ti layer 17 and the SiO₂ layer 15, thereby forming a cover electrode. The Au layer 18 is formed so as to have a thickness of about 1300 nm.

In the light emitting element 10 of the present embodiment configured as described above, a surface (−c-plane (N-face)) of the GaN substrate 11 on the side opposite to the stacked semiconductor layer 12, i.e., the side on which the semiconductor layer 12 is not stacked, serves as a main light emission surface S, and continuously-arranged protrusions 11a are formed at the main light emission surface S.

The protrusions 11a are formed such that a standing direction thereof is displaced from a stacking direction F1 (indicated by a dashed line in FIG. 1) of the semiconductor layer 12 (i.e., the standing direction is inclined with respect to the stacking direction F1).

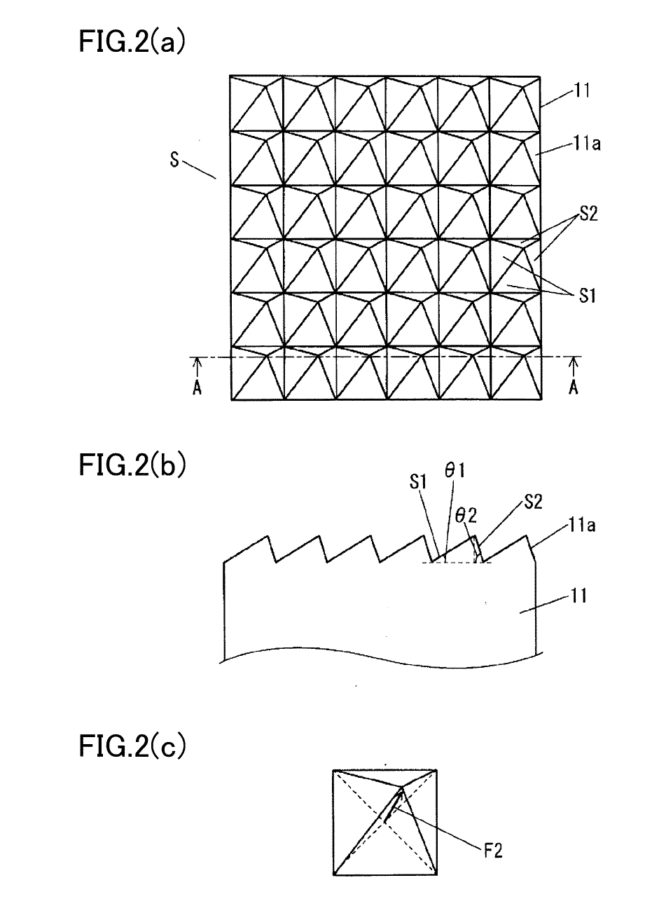

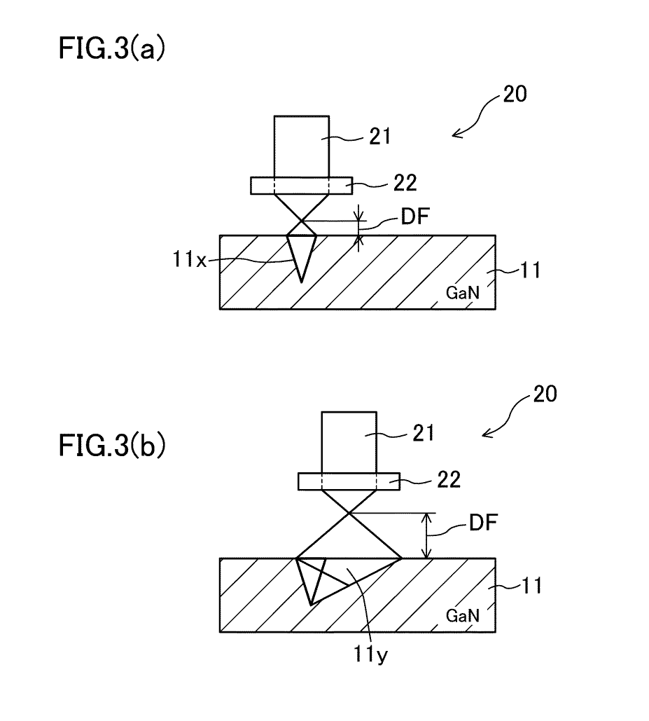

The protrusions 11a will be described with reference to FIGS. 2(a)-2(c), 3(a), and 3(b).

Referring to FIG. 2(a), each protrusion 11a is formed in such a pyramid shape that the center axis thereof is eccentric with respect to the stacking direction F1 of the semiconductor layer 12 (i.e., the protrusion 11a is inclined with respect to the stacking direction F1), and the protrusions 11a are arranged in a matrix of lines and columns. In the example illustrated in FIGS. 2(a)-2(c), the protrusion 11a is formed in a pointed quadrangular pyramid shape.

Each protrusion 11a is formed in such a quadrangular pyramid shape that the standing direction thereof is displaced from the stacking direction F1 of the semiconductor layer 12 and that the center axis thereof is eccentric with respect to the stacking direction F1 of the semiconductor layer 12. Thus, referring to FIG. 2(b), the protrusion 11a is in a quadrangular pyramid shape formed of a triangular surface S1 having a small inclination angle θ1 and having a broad area and a triangular surface S2 having a large inclination angle θ2 and having a small area. Thus, the protrusion 11a is in an asymmetrical shape.

The “standing direction” means the direction from the center of the base to the apex of the protrusion 11a (a standing direction F2 is indicated by an arrow in FIG. 2(c)). The inclined surfaces of the protrusions 11a are rough surfaces with fine asperities.

The protrusions 11a are formed at the processing step. At the processing step, the protrusions 11a can be formed by a laser scriber 20 illustrated in FIGS. 3(a) and 3(b) as an example of a cutter.

Referring to FIG. 3(a), an GaN substrate 11 is, from an end side to an opposite end side, irradiated with laser light through a collecting lens 22 adjusted such that a defocus amount DF of a laser device 21 is small, and the GaN substrate 11 is cut to form a deep V-shaped linear groove 11x. The angle of the bottom of the groove 11x is an acute angle. Then, during laser irradiation, the collecting lens 22 is adjusted such that the defocus amount DF gradually increases. Meanwhile, while the laser scriber 20 is being moved by a not-shown moving unit, the V-shaped linear groove 11x is, referring to FIG. 3(b), cut and expanded along one of walls of the groove 11x such that the depth of the one of the walls of the groove 11x gradually decreases in the direction perpendicular to a groove direction. As a result, a linear groove 11y having an increased width is formed. In this manner, an inclined surface of one protrusion 11a having a small inclination angle and an inclined surface of adjacent protrusion 11a having a large inclination angle can be formed.

The laser device 21 and the collecting lens 22 are moved in a grid pattern to form protrusions 11a between adjacent ones of the linear grooves 11y such that walls of adjacent ones of the linear grooves 11y intersecting each other form a triangular surface S1 of one protrusion 11a having a small inclination angle and a triangular surface S2 of an adjacent protrusion 11a having a large inclination angle.

Although metal (Ga) residue and a damaged layer are formed on the triangular surfaces S1, S2 formed by the laser device 21, the metal residue and the damaged layer can be removed by wet etching using a hydrochloric acid solution or a hydrofluoric acid solution or dry etching such as ICP etching or RIE etching.

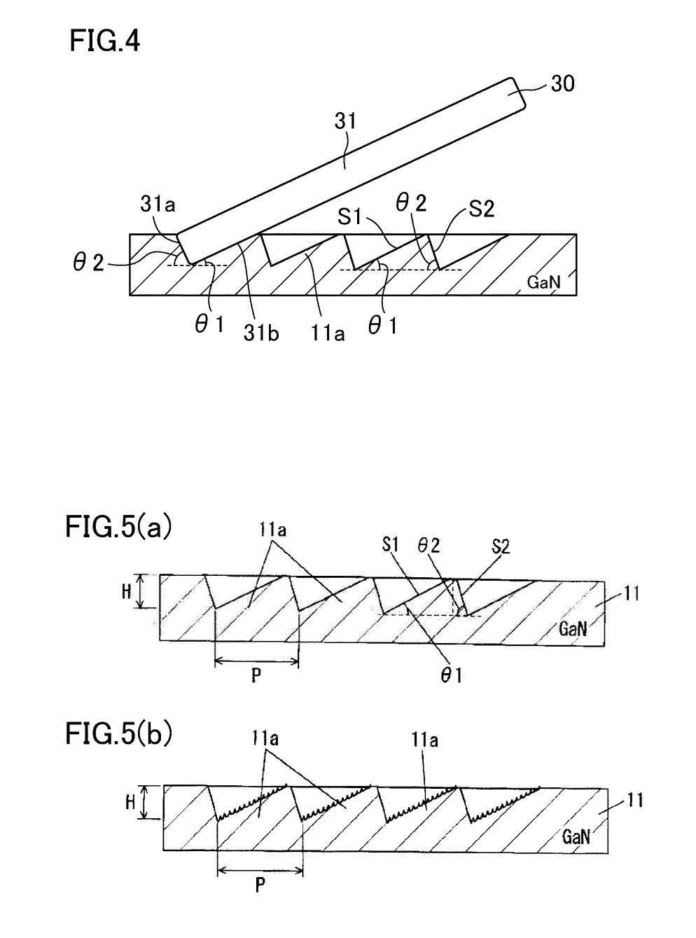

The protrusions 11a can be formed by a dicer 30 illustrated in FIG. 4 as an another example of the cutter. When the protrusions 11a are formed by the dicer 30, a rotary cutting blade 31 is inclined.

The dicer 30 is moved in a grid pattern in the state in which the dicer 30 is inclined such that the inclination angle of a blade edge 31a with respect to a main light emission surface and the inclination angle of a blade side surface 31b with respect to the main light emission surface are different from each other, thereby forming grooves. In this manner, protrusions 11a are formed such that a wall of one groove forms a triangular surface S1 of one protrusion 11a having a small inclination angle and that a wall of an adjacent groove forms a triangular surface S2 of the one protrusion 11a having a large inclination angle.

Referring to FIG. 5(a), in processing of the inclined surfaces of the protrusions 11a into rough surfaces with fine asperities, since the triangular surface S1 having the small inclination angle θ1 has an area broader than that of the triangular surface S2 having the large inclination angle θ2, advantages can be realized if the asperities are formed at least at the triangular surface S1 having the small inclination angle θ1. The fine asperities can be formed by etching using KOH. In etching using KOH, since a crystal face is roughened, fine asperities are not formed by etching when the inclination angle of the inclined surface is too large (see FIG. 5(b)). However, if the inclination angle falls within such a range that the crystal face can be exposed, the entirety of the protrusion 11a can be roughened.

A cross-sectional SEM photo image after formation of fine asperities is shown in FIG. 14(a). It can be observed that hexagonal pyramid shaped fine asperities are densely formed at an inclination surface inclined 25° from a −c-plane (N-face). On the other hand, when an N-face of a GaN substrate is etched with KOH, hexagonal pyramid shaped fine asperities are formed as illustrated in FIG. 14(e). However, due to influence of crystallizability of the substrate and an impurity doped amount of the substrate, a region is formed, where hexagonal pyramid shaped fine asperities are sparsely formed as illustrated in FIG. 14(d). This results in lowering of light extraction efficiency.

However, hexagonal pyramid shaped fine asperities can be, as illustrated in FIGS. 14(f) and 14(g), densely formed at inclined surfaces regardless of crystallizability of a substrate and an impurity amount of the substrate, and therefore lowering of the light extraction efficiency can be reduced. Moreover, fine asperities can be formed at an inclined surface on a plane, such as a m-plane, other than the c-plane in a GaN substrate, and the light extraction efficiency can be improved.

If the height of the protrusion 11a is set larger than the particle size (e.g., 10 μm) of a phosphor 101 as illustrated in FIG. 15, the particles of the phosphor 101 serving as a heat generation source can be arranged in proximity to a GaN substrate 102 having high thermal conductivity, and such a configuration is advantageous to an increase in luminance of a white LED.

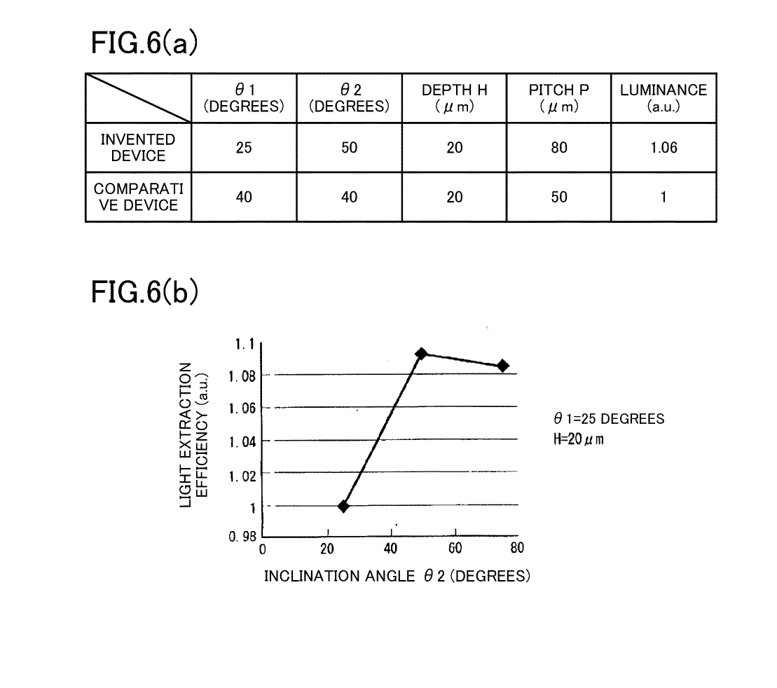

A light emitting element (hereinafter referred to as an “invented device”) including a GaN substrate 11 provided with protrusions 11a each having an inclination angle θ1 of 25° and an inclination angle θ2 of 50° was manufactured, and the luminance of the invented device was measured. For comparison, a light emitting element (hereinafter referred to as a “comparative device”) formed such that protrusions each have an inclination angle θ1 of 40° and an inclination angle θ2 of 40° to cause a standing direction of the protrusions and a stacking direction of a semiconductor layer to be coincident with each other was manufactured, and the luminance of the comparative device was measured. Note that a groove depth H was 20 μm in both of the invented device and the comparative device. Moreover, a pitch P was 80 μm in the invented device, and was 50 μm in the comparative device. Referring to FIG. 6(a), the luminance of the invented device was 1.06, where the luminance of the comparative device is expressed as “1.” This shows that the luminance of the invented device is improved as compared to that of the comparative device.

Simulation on the change in luminance in the case where the inclination angle θ2 changes from 25° to 80° while the inclination angle θ1 is fixed at 25° has been conducted, and the simulation results were presented in graph form. Referring to FIG. 6(b), the light extraction efficiency reaches about 1.09, i.e., a peak value, at an inclination angle θ2 of 50°, where the light extraction efficiency in the state in which the inclination angle θ1 and the inclination angle θ2 are identical to each other is expressed as “1.” Although such a result is different from the result, i.e., 1.06 in FIG. 6(a), for the actually-manufactured light emitting element, the simulation results in FIG. 6(b) show that differentiation between the inclination angle θ1 and the inclination angle θ2 tends to improve the luminance of the light emitting element.

Since the inclined surfaces of the protrusion 11a have different inclination angles as described above, the gentle triangular surfaces (gently-inclined surfaces) S1 and the steep triangular surfaces (steeply-inclined surfaces) S2 together form a three-dimensional shape. Thus, the probability that light emitted from the light emitting layer 12b reaches the main light emission surface S of the GaN substrate 11 at an angle below a critical angle can be increased. Consequently, the light extraction efficiency can be further improved as compared to, e.g., the conventional light emitting element of Patent Document 1 in which an inclination angle is the same among inclined surfaces.

Since the protrusions 11a are formed in a pointed shape, no surfaces parallel to the light emitting layer 12b are formed, and therefore broader inclined surfaces can be ensured due to the pointed shape of the protrusions 11a. Thus, the probability that light reaches the main light emission surface S at the angle below the critical angle can be further increased.

(Variations of the Embodiment)

Variations of the light emitting element of the embodiment of the present disclosure will be described with reference to drawings.

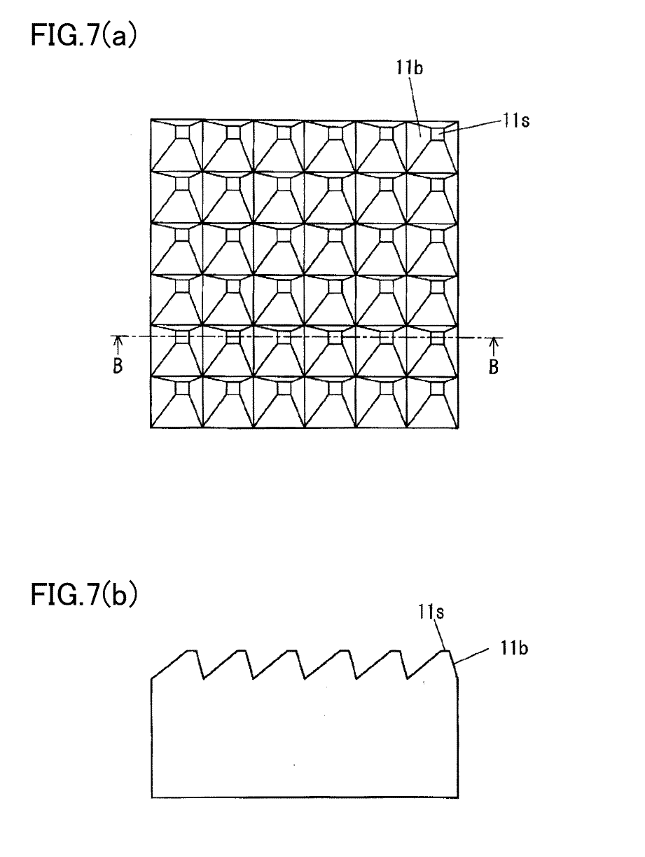

In a first variation illustrated in FIGS. 7(a) and 7(b), each protrusion 11b is formed in a truncated quadrangular pyramid shape. Since the protrusion 11b is formed in the truncated shape, a horizontal surface 11s is formed at the apex of the protrusion 11b. When a collet is, in mounting of a light emitting element, used to suck and deliver the light emitting element, the horizontal surfaces 11s closely contact a suction surface of the collet, and therefore the light emitting element can be stably delivered. Since a too broad area of the horizontal surfaces 11s results in reduction in improvement of light extraction efficiency, the total area of the horizontal surfaces 11s is preferably equal to or less than 30% of a chip area.

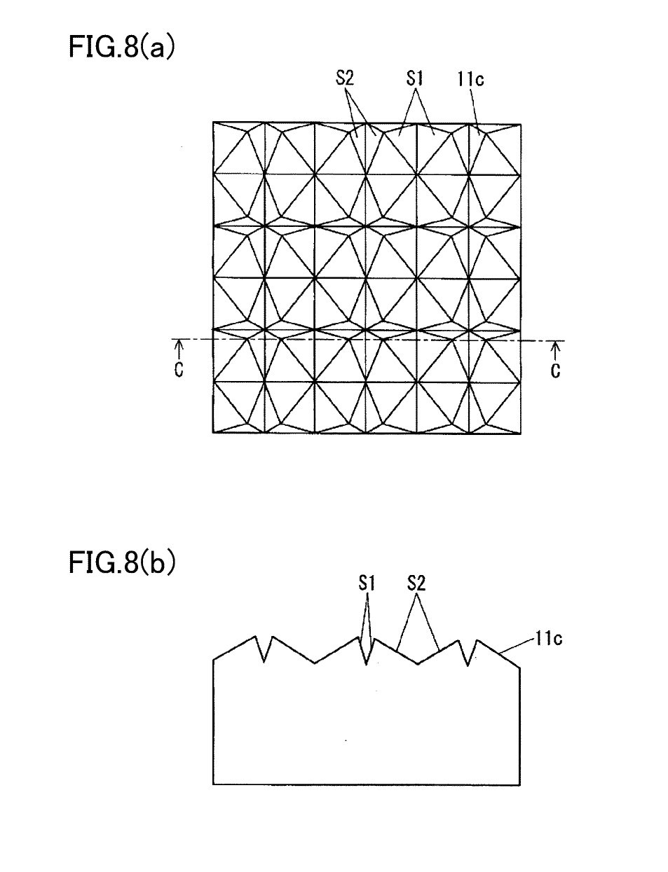

In a second variation illustrated in FIGS. 8(a) and 8(b), each protrusion 11c is formed in a pointed quadrangular pyramid shape, but the protrusions 11c are arranged such that triangular surfaces S1, which are inclined surfaces having a small inclination angle θ1, of adjacent ones of the protrusions 11c face each other and that triangular surfaces S2, which are inclined surfaces having a large inclination angle θ2, of adjacent ones of the protrusions 11c face each other.

Of the inclined surfaces of the protrusions 11a illustrated in FIGS. 2(a)-2(c), the inclined surfaces having the same inclination angle point in the same direction. Thus, there is a possibility that inclination of light emitted from the protrusions 11a becomes unbalanced among the protrusions 11a. However, of the inclined surfaces of the protrusions 11c illustrated in FIGS. 8(a) and 8(b), the inclined surfaces having the same inclination angle point in different directions, and therefore inclination of light emitted from the protrusions 11c can be uniform among the protrusions 11c.

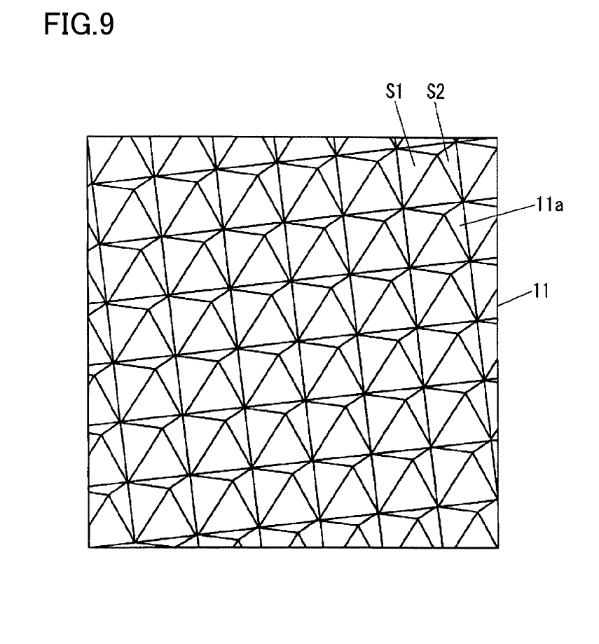

In a third variation illustrated in FIG. 9, a line direction and a column direction of protrusions 11a arranged in a matrix of lines and columns are non-parallel to end surfaces of a GaN substrate 11.

In the example illustrated in FIG. 9, the line direction and the column direction of the protrusions 11a are each inclined 15° from the end surface of the GaN substrate 11.

In order to cause the line direction and the column direction of the protrusions 11a to be non-parallel to the end surfaces of the GaN substrate 11, the laser device 21 illustrated in FIGS. 3(a) and 3(b) or the dicer 30 illustrated in FIG. 4 is, in formation of grooves by the laser device 21 or the dicer 30, moved so as to be inclined with respect to scribe grooves for dividing a wafer.

The protrusions 11a are formed at the GaN substrate 11 as described above. Thus, when a wafer to be the GaN substrates 11 is divided into pieces by breaking after the semiconductor layer 12 is stacked on the wafer and scribe grooves for diving the light emitting elements 10 from each other are formed at the wafer, the wafer can be prevented from being mistakenly divided at the groove between adjacent ones of the protrusions 11a by breaking.

In the example illustrated in FIG. 9, the base of the protrusion 11a is formed in a substantially square shape, and the GaN substrate 11 is formed in a substantially square shape. Thus, the inclination angle of the line direction of the protrusions 11a with respect to the end surface of the GaN substrate 11 and the inclination angle of the column direction of the protrusions 11a with respect to the end surface of the GaN substrate 11 are the same as each other, but may be different from each other. Either one of the line direction or the column direction may be non-parallel to the end surfaces of the GaN substrate 11.

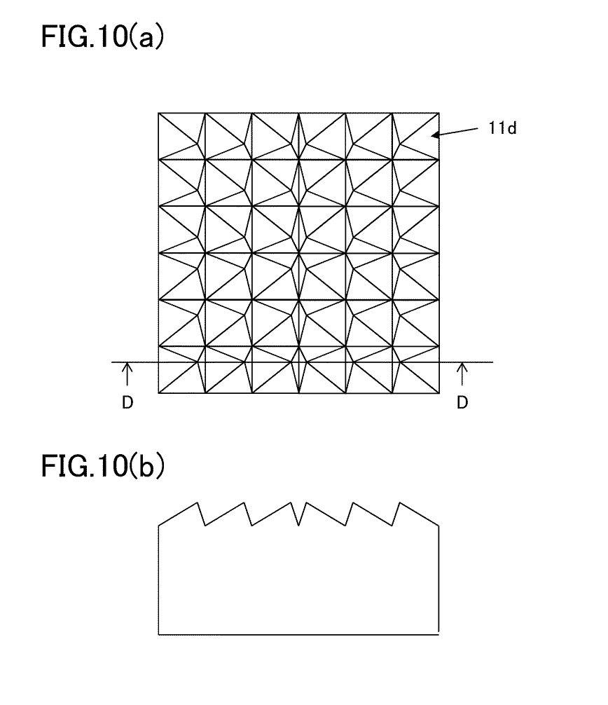

In a fourth variation illustrated in FIGS. 10(a) and 10(b), each protrusion 11d is formed in a pointed quadrangular pyramid shape, and the protrusions 11d are arranged such that the apexes thereof are symmetric with respect to the center of a chip. Of the inclined surfaces of the protrusions 11a illustrated in FIGS. 2(a)-2(c), the inclined surfaces having the same inclination angle point in the same direction. Thus, there is a possibility that inclination of light emitted from the protrusions 11a becomes unbalanced among the protrusions 11a. However, since the protrusions 11d illustrated in FIGS. 10(a) and 10(b) are arranged such that the apexes thereof are symmetric with respect to the center of the chip, light can be emitted from the protrusions 11d in a symmetrical pattern.

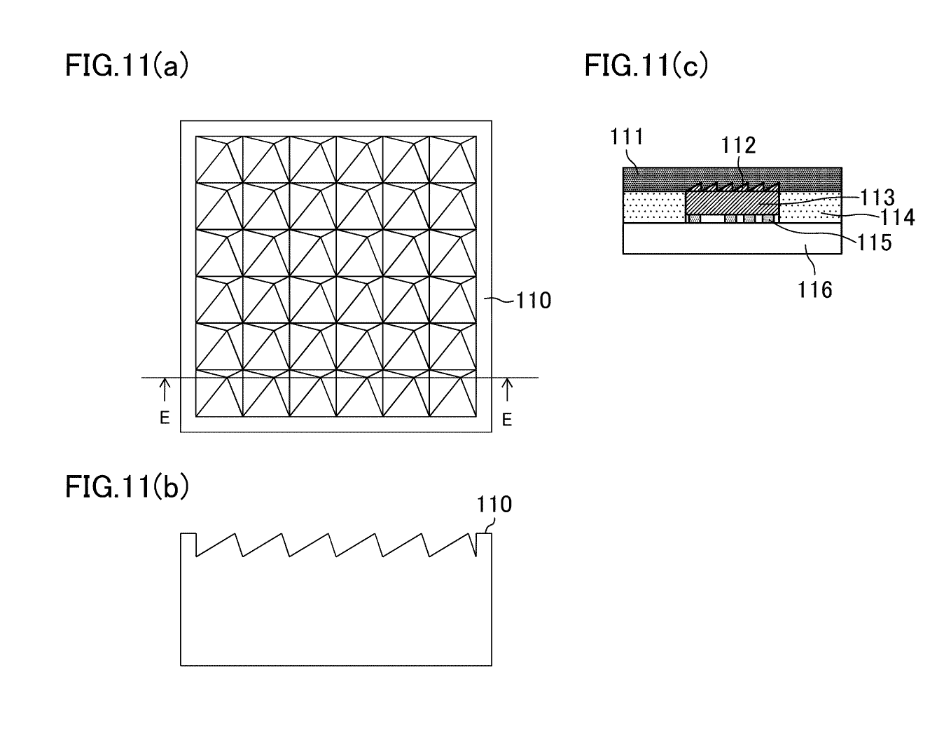

In a fifth variation illustrated in FIGS. 11(a) and 11(b), a non-processed part 110 is formed along the outer periphery of a chip. In mounting of a chip of a white LED on a package, resin (underfill 114) mixed with a high-refractive-index material is, in order to increase light intensity, sometime applied to the periphery of an LED chip 113 as illustrated in FIG. 11(c). A phosphor layer 111 is formed on a light emission surface 112 of the LED chip 113 with the light emission surface 112 facing upward, and the LED chip 113 is mounted on a mount substrate 116 through, e.g., Au bumps 115. In this variation, the non-processed part 110 formed at the outer periphery of the chip can prevent underfill from flowing over the chip. In order to prevent the underfill from flowing over the chip, the width of the non-processed part 110 is preferably equal to or greater than 5 μm. In order to ensure improvement of light extraction efficiency, the area of the non-processed part 110 is preferably equal to or less than 30% of a chip area.

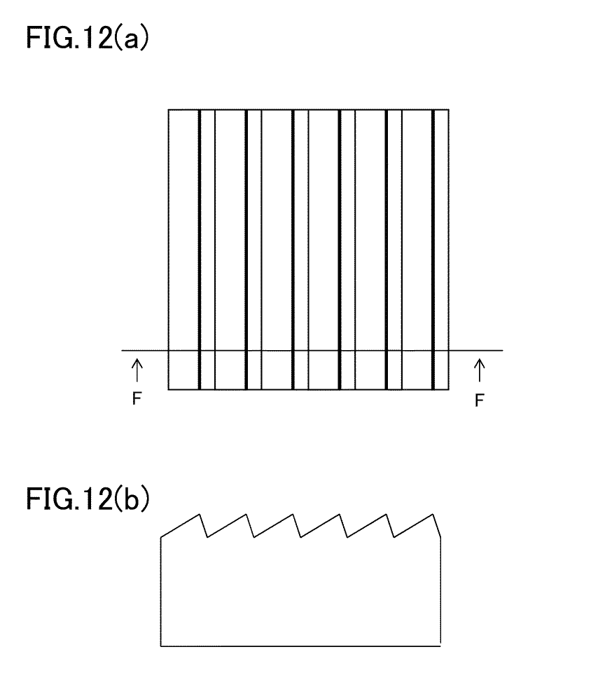

In a sixth variation illustrated in FIGS. 12(a) and 12(b), protrusions are formed only in a line direction or a column direction. Even in this structure, improvement of light extraction efficiency can be ensured, and a processing time can be shortened.

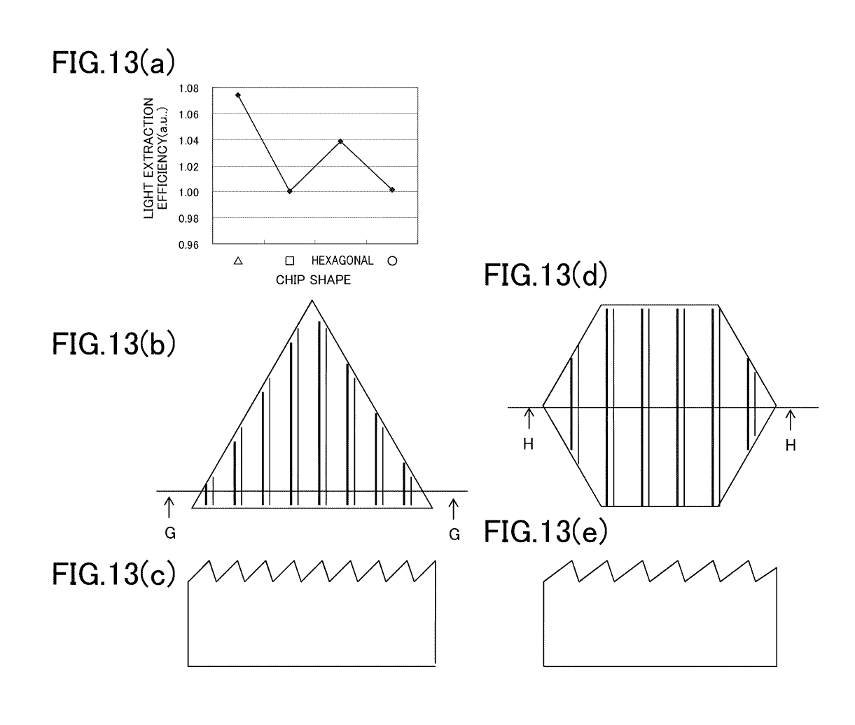

FIG. 13(a) shows measurement results on the relationship between a chip shape and light extraction efficiency. A chip area is the same, i.e., an area of 8 mm×0.8 mm, among chips, and a chip thickness is 100 μm. In the cases of a triangular chip and a hexagonal chip, light extraction through a chip side surface can be increased, and therefore the light extraction efficiency can be increased as compared to that of a rectangular chip. Referring to FIGS. 13(b)-13(e), if the present disclosure is applied to the triangular chip and the hexagonal chip, higher light extraction efficiency can be realized.

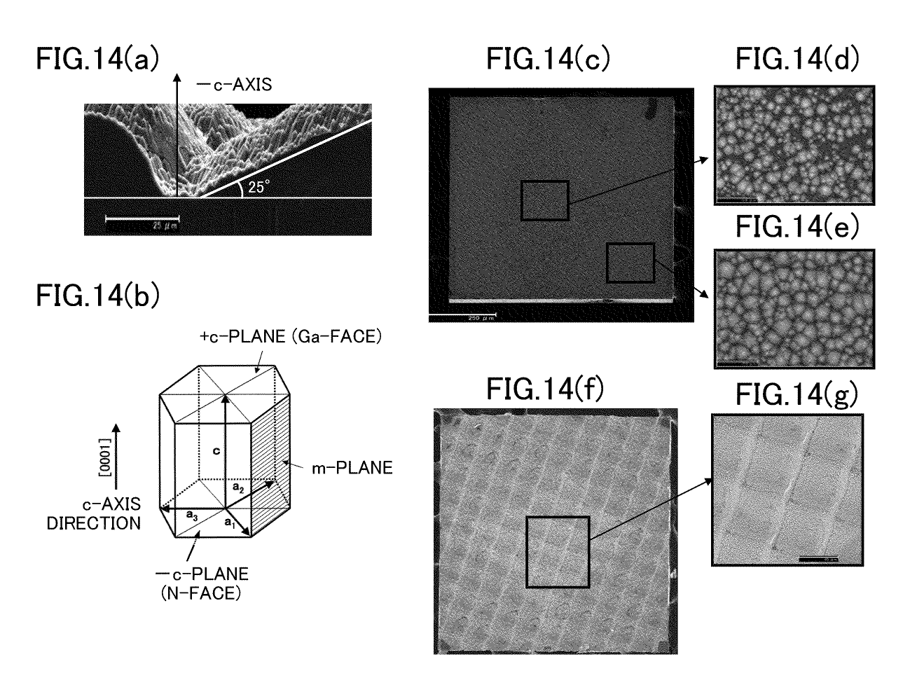

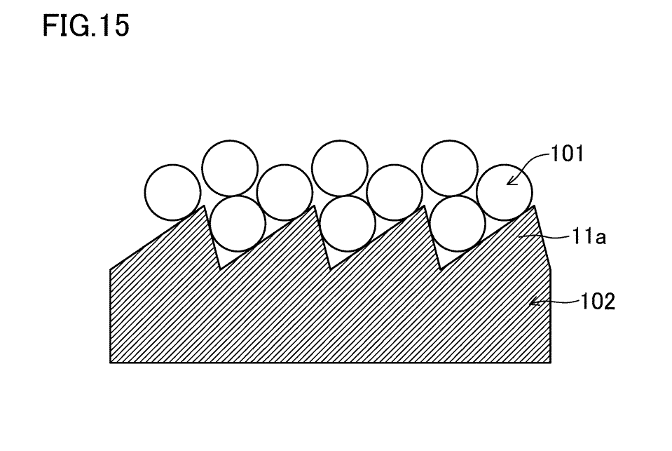

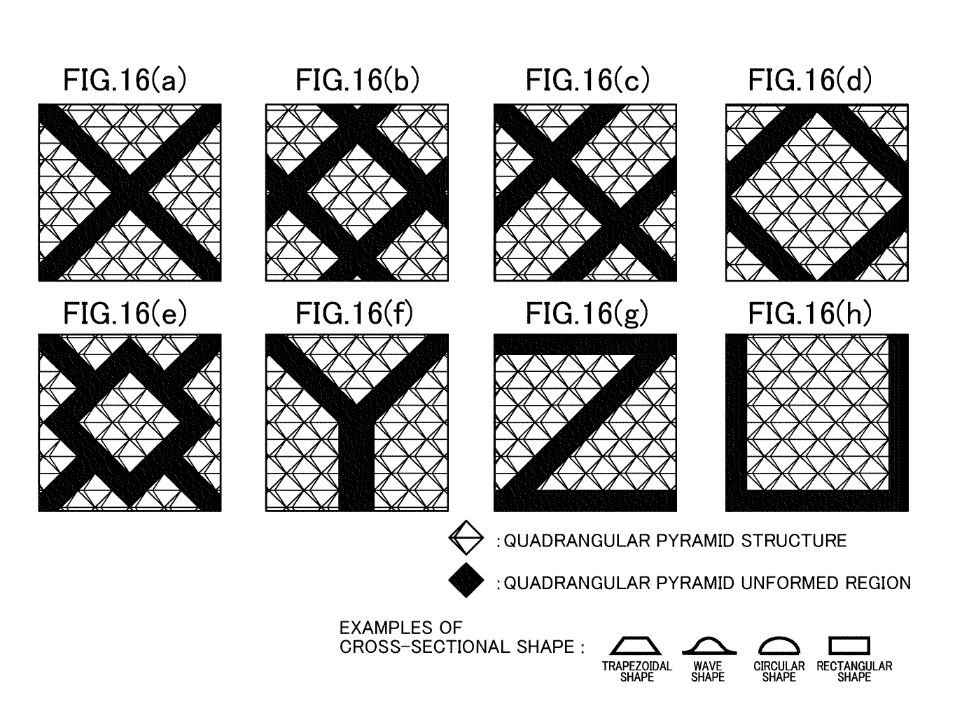

FIGS. 16(a)-16(h) illustrate variations in which a region (quadrangular pyramid unformed region) where no quadrangular pyramid shaped protrusions are formed is formed at part of a chip. Since the quadrangular pyramid unformed region is continuously formed, the stiffness of the chip can be increased, and therefore cracking of the chip can be reduced. The cross section of the chip in the quadrangular pyramid unformed region can be formed in, e.g., a trapezoidal shape, a wave shape, a circular shape, or a rectangular shape.

### INDUSTRIAL APPLICABILITY

According to the present disclosure, the light extraction efficiency can be further improved. Thus, the present disclosure is suitable for a light emitting element in which a semiconductor layer including a light emitting layer is stacked on a substrate and for the method for manufacturing the light emitting element.

### DESCRIPTION OF REFERENCE CHARACTERS

10 Light emitting element
11 GaN Substrate
11a, 11b, 11c Protrusion
11s Horizontal Surface
11x Linear Groove
11y Linear Groove
12 Semiconductor Layer
12a N-GaN Layer
12b Light Emitting Layer
12c P-GaN Layer
13 n-Electrode
13a Al Layer
13b Ti Layer
13c Au Layer
14 p-Electrode
14a Ni Layer
14b Ag Layer
SiO₂ Layer
16 First Ti Layer
17 Second Ti Layer
18 Au Layer
20 Laser Scriber
21 Laser Device
22 Collecting Lens
30 Dicer
31 Rotary Cutting Blade
31a Blade Edge
31b Blade Side Surface
S Main Light Emission Surface
S1, S2 Triangular Surface
θ1, θ2 Inclination Angle
F1 Stacking Direction
F2 Standing Direction

1. A light emitting element in which a semiconductor layer including a light emitting layer is stacked on a substrate and in which a surface of the substrate opposite to the stacked semiconductor layer serves as a main light emission surface, comprising:
protrusions continuously arranged on the main light emission surface,
wherein a standing direction of each protrusion is displaced from a stacking direction of the semiconductor layer.

2. The light emitting element of claim 1, wherein
fine asperities are formed at least at an inclined surface of each protrusion having a small inclination angle.

3. The light emitting element of claim 1 or 2, wherein
the protrusions are arranged in a matrix of lines and columns, and
a line direction and/or a column direction of the protrusions are non-parallel to an end surface of the substrate.

4. The light emitting element of claim 1 or 2, wherein
each protrusion is formed in a pointed shape or a truncated shape.

5. The light emitting element of claim 4, wherein
each protrusion is formed in such a pyramid shape that a center axis thereof is eccentric with respect to the stacking direction of the semiconductor layer.

6. A method for manufacturing a light emitting element, comprising:
a stacking step of stacking a semiconductor layer including a light emitting layer on a substrate; and
a processing step of continuously forming protrusions each standing in a direction displaced from a stacking direction of the semiconductor layer by forming grooves at a main light emission surface of the substrate opposite to the stacked semiconductor layer while a cutter is being moved in a grid pattern, each groove being formed of a wall having a small inclination angle and a wall having a large inclination angle.

7. The method of claim 6, wherein
at the processing step,
the main light emission surface is irradiated with laser light by a laser device serving as the cutter to form V-shaped grooves, and then,
while a defocus amount of a collecting lens is being increased, each V-shaped groove is, in order to form the grooves having an increased width, expanded along one of walls of the each V-shaped groove such that a depth of the one of walls of the each V-shaped groove gradually decreases in a direction perpendicular to a groove direction.

8. The method of claim 6, wherein
at the processing step, a rotary cutting blade serving as the cutter is moved in a state in which the rotary cutting blade is inclined such that an inclination angle of a blade edge surface of the rotary cutting blade with respect to the main light emission surface and an inclination angle of a blade side surface of the rotary cutting blade with respect to the main light emission surface are different from each other, thereby forming the grooves.

9. The method of claim 6, wherein
at the processing step, when the cutter is moved in the grid pattern to form the grooves, the cutter is moved in a direction non-parallel to a scribe groove to be an end surface of the substrate.

10. The light emitting element of claim or 2, wherein
the substrate is made of c-plane GaN.

11. The light emitting element of claim 10, wherein
the inclined surface of each protrusion is a surface inclined from −c-plane which is an N-face of the substrate.
